(19) United States
(12) Patent Application Publication
(10) Pub. No.: US 2012/0044625 A1
(43) Pub. Date: Feb. 23, 2012

(54) CARD MODULE AND METHOD FOR MANUFACTURING CARD MODULE

(75) Inventors: Masakazu Muranaga, Tokyo (JP); Kimihiro Maruyama, Tokyo (JP); Koki Sato, Tokyo (JP); Mitsuru Kobayashi, Tokyo (JP)

(73) Assignee: FUJITSU COMPONENT LIMITED, Tokyo (JP)

(21) Appl. No.: 13/173,685

(22) Filed: Jun. 30, 2011

(30) Foreign Application Priority Data
Aug. 23, 2010 (JP) 2010-186531

(51) Int. Cl. H05K 7/00; H05K 3/34; G06F 1/16

(52) U.S. Cl. 361/679.32; 29/840

(57) ABSTRACT

A card module includes a top case, a bottom case engaged with the top case, a substrate being positioned between the top case and the bottom case and including a first connection terminal, an electronic device provided in a space formed by engaging the top case with the bottom case, and a terminal substrate including a first surface on which a second connection terminal is formed, a second surface on which an electrode terminal is formed, and a through-hole in which a connection electrode is formed. The first connection terminal is connected to the second connection terminal. The second connection terminal and the electrode terminal are connected via the connection electrode.

### BACKGROUND OF THE INVENTION

1. Field of the Invention

The present invention generally relates to a card module and a method for manufacturing the card module.

2. Description of the Related Art

In recent years, card modules are used as external data storage media. An SD (Secure Digital) card having a semiconductor memory (e.g., flash memory) installed therein or an MMC (Multi-Media Card) are examples of the card modules. By connecting the card module to a card slot provided to an electronic device such as a personal computer or a digital camera, data can be stored in the card module and data can be read out from the card module. Because the card module has a thin and small shape, the card module is widely used for various purposes.

Not only is the wide use of the card module desired but also the increase of storage capacity of the card module and the improvement of performance of the card module are desired. However, because of the thin and small size of the card module, the number of electronic devices and the size of electronic devices that can be mounted on the card module are limited.

### SUMMARY OF THE INVENTION

The present invention may provide a card module and a method for manufacturing the card module that substantially eliminate one or more of the problems caused by the limitations and disadvantages of the related art.

Features and advantages of the present invention will be set forth in the description which follows, and in part will become apparent from the description and the accompanying drawings, or may be learned by practice of the invention according to the teachings provided in the description. Objects as well as other features and advantages of the present invention will be realized and attained by a card module and a method for manufacturing the card module particularly pointed out in the specification in such full, clear, concise, and exact terms as to enable a person having ordinary skill in the art to practice the invention.

To achieve these and other advantages and in accordance with the purpose of the invention, as embodied and broadly described herein, the invention provides a card module including a top case, a bottom case engaged with the top case, a substrate being positioned between the top case and the bottom case and including a first connection terminal, an electronic device provided in a space formed by engaging the top case and the bottom case, and a terminal substrate including a first surface on which a second connection terminal is formed, a second surface on which an electrode terminal is formed, and a through-hole in which a connection electrode is formed, wherein the first connection terminal is connected to the second connection terminal, wherein the second connection terminal and the electrode terminal are connected via the connection electrode.

Other objects and further features of the present invention will be apparent from the following detailed description when read in conjunction with the accompanying drawings.

### BRIEF DESCRIPTION OF THE DRAWINGS

FIG. 1 is a cross-sectional view of a card module according to a related art example;

FIG. 2A is a schematic diagram illustrating a back surface of a card module according to a first embodiment of the present invention;

FIG. 2B is a cross-sectional view of the card module taken along a dash-dot line 2X1-2X2 in FIG. 2A;

FIGS. 3A and 3B are schematic diagrams for describing a method for manufacturing a card module according to the first embodiment of the present invention;

FIGS. 4A and 4B are schematic diagrams for describing a terminal substrate of a card module according to a first embodiment of the present invention;

FIGS. 5A and 5B are schematic diagrams for describing another method for manufacturing a card module according to the first embodiment of the present invention;

FIG. 6A is a top perspective view illustrating a substrate and a terminal substrate according to a first example of the first embodiment of the present invention;

FIG. 6B is a bottom perspective view illustrating a terminal substrate according to the first example of the first embodiment of the present invention;

FIG. 7A is a top perspective view illustrating a substrate and a terminal substrate according to a second example of the first embodiment of the present invention;

FIG. 7B is a bottom perspective view illustrating a terminal substrate according to the second example of the first embodiment of the present invention;

FIG. 8A is a top perspective view illustrating a substrate and a terminal substrate according to a third example of the first embodiment of the present invention;

FIG. 8B is a bottom perspective view illustrating a terminal substrate according to the third example of the first embodiment of the present invention;

FIG. 9A is a top perspective view illustrating a substrate and a terminal substrate according to a fourth example of the first embodiment of the present invention;

FIG. 9B is a bottom perspective view illustrating a terminal substrate according to the fourth example of the first embodiment of the present invention;

FIG. 10A is a top perspective view illustrating a substrate and a terminal substrate according to a fifth example of the first embodiment of the present invention;

FIG. 10B is a bottom perspective view illustrating a terminal substrate according to the fifth example of the first embodiment of the present invention;

FIG. 11 is a perspective view of a substrate of a card module according to a second embodiment of the present invention;

FIGS. 12A and 12B are schematic diagrams for describing a method for manufacturing a card module according to the second embodiment of the present invention;

FIG. 13 is a perspective view of a substrate of another card module according to a second embodiment of the present invention;

FIG. 14A is a schematic diagram illustrating a back surface of another card module according to the second embodiment of the present invention;

FIG. 14B is a cross-sectional view of the card module taken along a dash-dot line 14X1-14X2 in FIG. 14A;

FIG. 15A is a schematic diagram illustrating a back surface of yet another card module according to the second embodiment of the present invention;

FIG. 15B is a cross-sectional view of the card module taken along a dash-dot line 15X1-15X2 in FIG. 15A;

FIG. 16A is a schematic diagram illustrating a back surface of a card module according to a third embodiment of the present invention;

FIG. 16B is a cross-sectional view of the card module taken along a dash-dot line 16X1-16X2 in FIG. 2A; and

FIGS. 17A-17C are schematic diagrams for describing another method for manufacturing a card module according to the third embodiment of the present invention.

### DESCRIPTION OF THE PREFERRED EMBODIMENTS

In the following, embodiments of the present invention will be described with reference to the accompanying drawings. In the drawings, arrows X1-X2 indicate horizontal directions of the below-described card modules 100, 200, 300, and 1000; arrows Y1-Y2 indicate vertical directions of the below-described card modules 100, 200, 300, and 1000; arrows Z1-Z2 indicate the depth directions of the below-described card modules 100, 200, 300, and 1000.

### First Embodiment

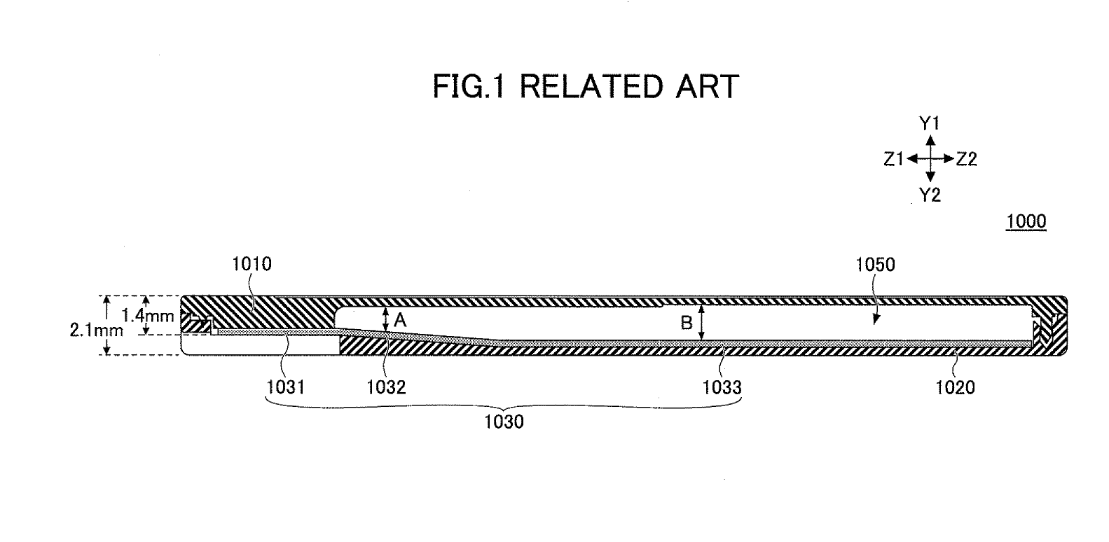

First, a card module 1000 according to a related art example is described with reference to FIG. 1.

The card module 1000 includes a top case 1010, a bottom case 1020, and a substrate 1030 provided between the top case 1010 and the bottom case 1020. Further, an electronic device (not illustrated) is allowed to be installed on the substrate 1030 in a space 1050 in-between the top case 1010 and the bottom case 1020.

The substrate 1030 includes plural connection terminals (electrode terminals) 1031 provided on a portion of a front surface of the substrate 1030 for connecting to a corresponding electrode terminal(s) of a card slot (not illustrated). The substrate 1030 is mounted on the bottom case 1020 in a manner exposing the portion of the surface of the substrate 1030 on which the connection terminals 1031 are provided. It is to be noted that the connection terminal 1031 is to be connected to the electronic device (not illustrated) provided in the space 1050 via the substrate 1030.

Specifications such as the size and the length of the card module 1000 are defined so that the card module 1000 can be connected to a card slot (not illustrated). For example, the thickness of the card module 1000 is approximately 2.1 mm. Further, the distance from an outer surface of the top case 1010 to the surface of the connection terminal 1031 of the substrate 1030 is approximately 1.4 mm. In order to mount a maximum amount of electronic devices or the largest possible electronic device on the card module 1000, it is necessary to increase the size of the space 1050. Therefore, a portion of the bottom case 1020 corresponding to an area of the space 1050 is formed with a small thickness. Accordingly, the substrate 1030 is mounted in a manner contacting an inner (surface) side of the bottom case 1032 inside the space 1050 and bent in a manner extending towards the area where the connection terminal 1031 is to be provided.

Accordingly, a portion of the space 1050 corresponding to a bent (inclined) area 1032 of the substrate 1030 has a height “A” which is less than a height “B” of a portion of the space 1050 corresponding to a flat area 1033 of the substrate 1030. Therefore, even if an electronic device or the like can be mounted on the flat area 1033 of the substrate 1030, it may be difficult for the electronic device or the like to be mounted on the bent area 1032 due to the difference of height in the space 1050. Thus, the amount of electronic devices and the size of electronic devices that can be installed inside the card module are limited.

### (Card Module)

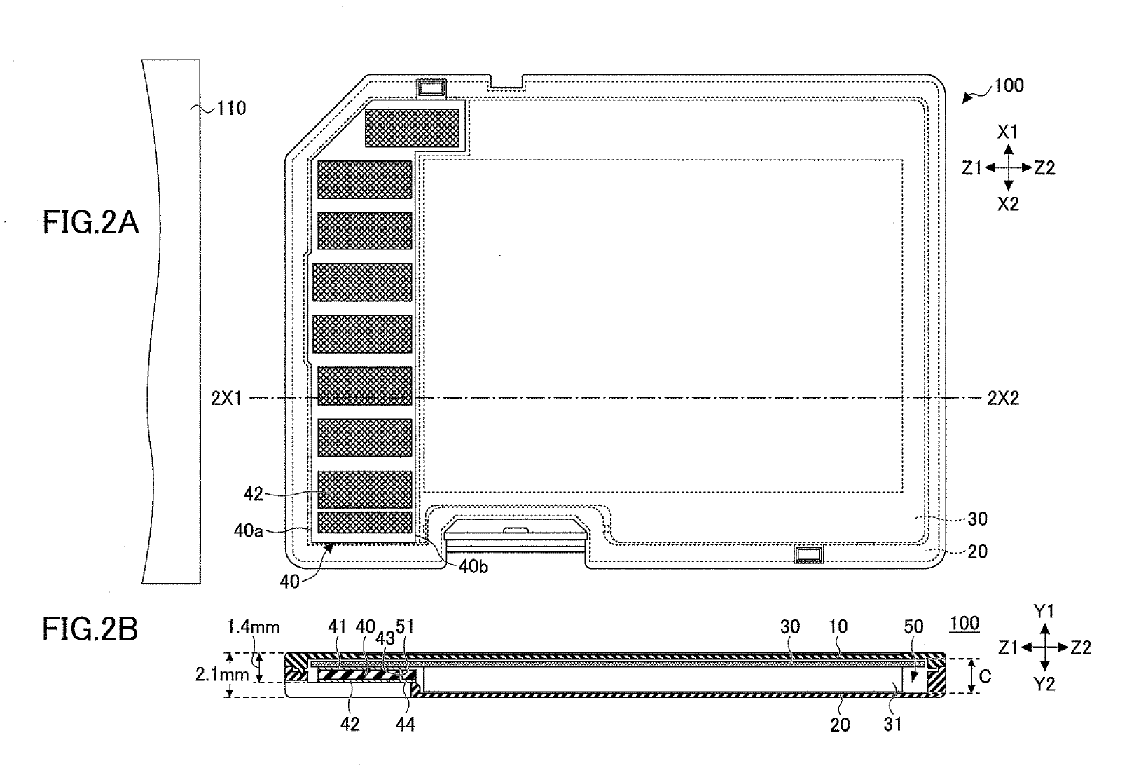

Next, a card module 100 according to a first embodiment of the present invention is described. As illustrated in FIGS. 2A and 2B, the card module 100 includes a top case 10, a bottom case 20 engaged with the top case 10, and a substrate 30 provided between the top case 10 and the bottom case 20. The substrate 30 is mounted in contact with an inner surface of the top case 10 without any bending of the substrate 30. One end part of the substrate 30 is connected to a terminal substrate 40 including an electrode terminal 42 for connecting to an electrode terminal (not illustrated) of a card slot 110. The terminal substrate 40 is formed of, for example, polyimide or glass epoxy. The terminal substrate 40 has one surface on which a connection terminal 41 is formed and another surface on which the electrode terminal 42 is formed. The connection terminal 41 and the electrode terminal 42 are connected to a connection electrode 51 formed in the through-hole 43. The terminal substrate 40 has a first end 40a being positioned towards a side of the card module from which the card module is inserted (e.g., inserted towards direction Z1 of FIG. 2A) to a card slot 110 and the through-hole 43 being positioned towards a second end 40b of the terminal substrate 40 located opposite from the first end 40a (see, for example, FIG. 2A). The connection terminal 41, the electrode terminal 42, and the connection electrode 51 may be formed with the same material or with one or more different materials. Furthermore, the connection terminal 41, the electrode terminal 42, and the connection electrode 51 may be formed substantially at the same time or formed separately in different steps. The terminal substrate 40 is electrically connected to the substrate 30, for example, by soldering the connection terminal 41 to the below-described connection terminal 32 (32a-32e) of the substrate 30. The bottom case 20 is formed in a manner exposing the electrode terminal 42.

A space 50 is defined by an area surrounded by the top case 10 and the bottom case 20. As described above, the substrate 30 is mounted in contact with the inner surface of the top case 10 without any bending of the substrate 30. Accordingly, the space 50 has a height C which is substantially constant throughout the inside of the space 50. Accordingly, compared to the above-described card module 1000 of the related art example, a greater number of electronic devices and larger electronic devices can be mounted to the card module 100 of this embodiment of the present invention. Thus, in order to make the most of the space 50 of the card module 100, it is preferable to mount the substrate 30 in contact with the inner surface of the top case 10 and install an electronic device(s) 31 on a surface of the substrate 30 facing the space 50. FIG. 2A is a schematic diagram illustrating a back surface of the card module 100 according to the first embodiment of the present invention. FIG. 2B is a cross-sectional view of the card module 100 taken along a dash-dot line 2X1-2X2 in FIG. 2A.

### (Method for Manufacturing Card Module)

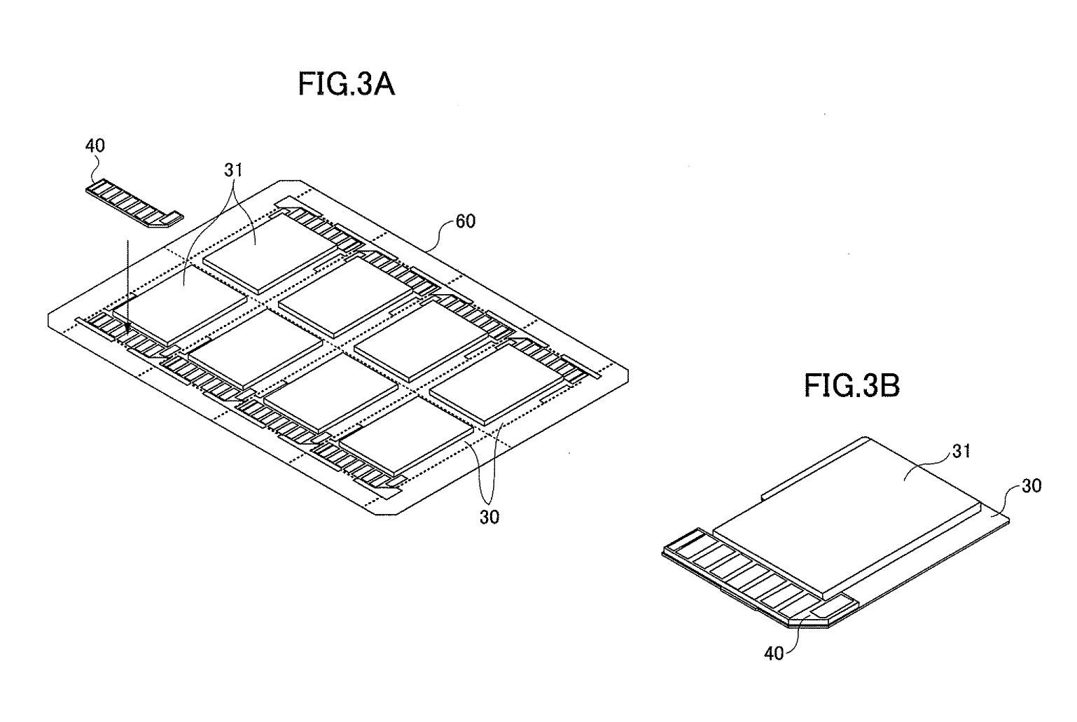

Next, a method for manufacturing a card module 100 according to the first embodiment of the present invention is described. As illustrated in FIGS. 3A and 3B, a sheet substrate 60, which can be cut into one or more separate substrates 30, is prepared. Then, one or more terminal substrates 40 and one or more electronic devices 31 are placed on the sheet substrate 60 and soldered to the sheet substrate 60 by using reflow. Then, the sheet substrate 60 is cut into one or more separate substrates 30. Each of the substrates 30, which is cut off from the sheet substrate 60, is provided between a corresponding top case 10 and a corresponding bottom case 20. Thereby, one or more card modules 100 can be obtained. Because the soldering process using reflow is performed at a single time for connecting the substrates 30 and the terminal substrates 40 and connecting the substrates 30 and the electronic devices 31, the cost for manufacturing the card module 100 can be reduced. That is, the manufacturing cost of the card module 100 can be reduced by soldering the substrates 30 to the terminal substrate 40 substantially at the same time of soldering the electronic devices 31 to the substrates 30.

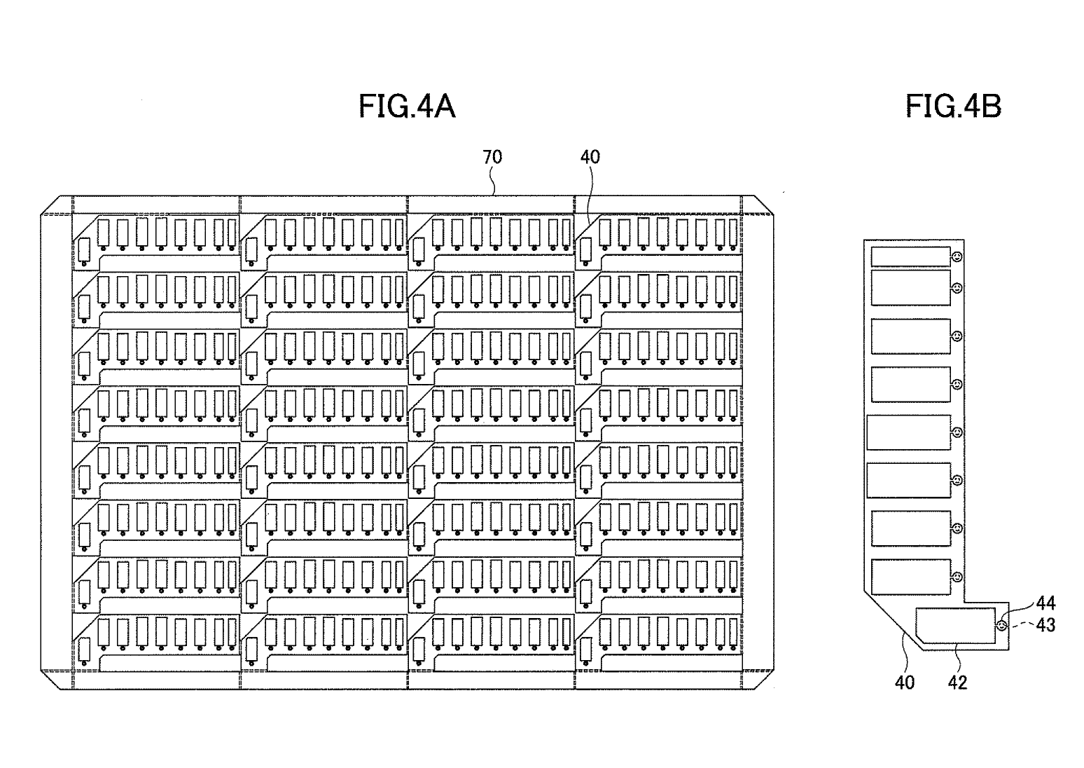

FIG. 4A is a schematic diagram illustrating the sheet substrate 70 according to an embodiment of the present invention. FIG. 4B is a schematic diagram illustrating a terminal substrate 40 cut out from the sheet substrate 70 according to the first embodiment of the present invention. As illustrated in FIG. 4B, the terminal substrate 40 includes the electrode terminal 42 and a land part 44 connected to the electrode terminal 42. By forming a through-hole 43 in the land part 44, the electrode terminal 42 is connected to a connection terminal 41 provided on a back surface of the terminal substrate 40. It is preferable to form the through-hole 43 on a predetermined side of the terminal substrate 40, so that the through-hole 43 is positioned on a side of the card module 100 farther from a card slot 110 when the card module 100 is inserted into the card slot 110. In other words, it is preferable for the position of the through-hole 43 of the card module 100 to be positioned more inward (e.g., towards direction Z2 of FIG. 2B) compared to the electrode terminal 42. Because the connection electrode 51 inside the through-hole 43 is formed of, for example, plating, the connection electrode 51 is substantially susceptible to stress or the like. Accordingly, it is preferable for the connection electrode 51 of the through-hole 43 to avoid contact with the electrode terminal (not illustrated) of the card slot 110 as much as possible. By providing the connection electrode 51 in a manner avoiding contact with the electrode terminal (not illustrated) of the card slot 110, reliable electric connection can be achieved between the card module 100 and the card slot 110. As long as the through-hole 43 is provided in a position avoiding contact with an electrode terminal (not illustrated) of the card slot 110, the position of the through-hole 43 is not limited in particular. For example, the through-hole 43 may be positioned in an area where the electrode terminal 42 is to be formed.

The connection electrode 51 may be formed inside the through-hole 43 by performing the following method. For example, by forming an opening (which is to become the through-hole 43) at the land part 44 formed on the first and back surface of the terminal substrate 40 and performing a metal plating method, the connection terminal 51 can be formed inside the through-hole 43.

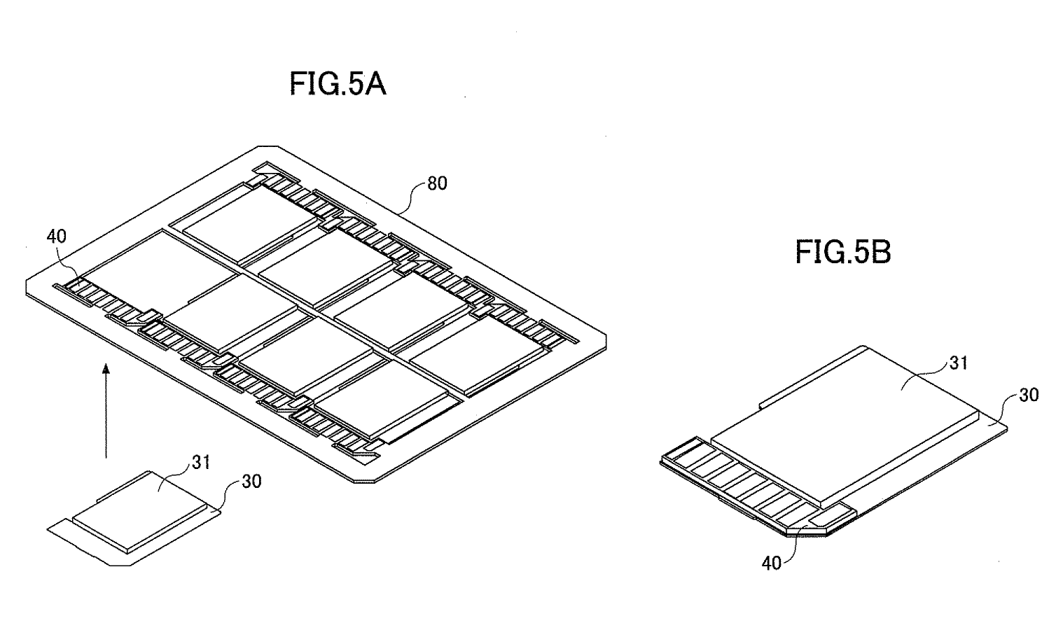

Next, another method for manufacturing a card module 100 according to an embodiment of the present invention is described. As illustrated in FIGS. 5A and 5B, a sheet substrate 80, which can be cut into one or more separate terminal substrates (electrode terminals) 40, is prepared. Then, the sheet substrate 80 is placed on plural substrates 30. Each of the substrates 30 has an electronic device 31 mounted thereon. Then, the sheet substrate 80 and the plural substrates 30 are soldered together by using reflow. Then, the sheet substrate 80 is cut into one or more separate substrates 30. Then, each of the substrates 30 cut off from the sheet substrate 80 is provided between a corresponding top case 10 and a corresponding bottom case 20. Thereby, one or more card modules 100 can be obtained. With this method, the soldering process using reflow is performed. The first soldering process is performed when mounting the electronic device 31 on the substrate 30. The second soldering process is performed when mounting the terminal substrates 40 on the sheet substrate 80.

### (Terminal Substrate)

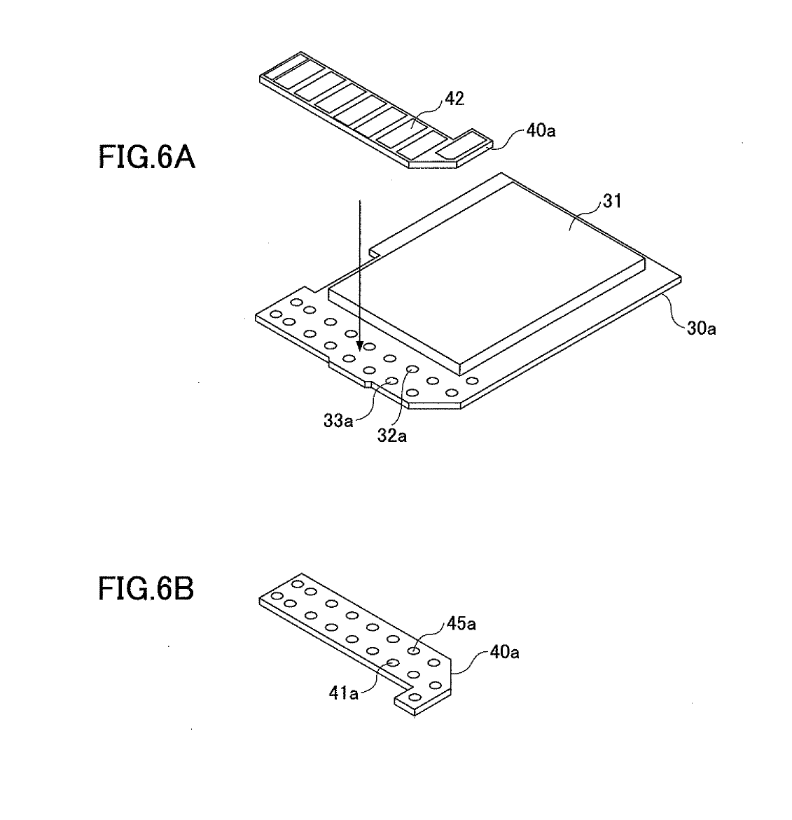

Next, the substrate 30 (30a-30e) and the terminal substrate 40 (40a-40e) used in the card module 100 according to the first embodiment of the present invention are described. In the below-described FIGS. 6A-10B, components such as the land part 44 are omitted for the sake of convenience.

FIG. 6A is a top perspective view illustrating a substrate 30a and a terminal substrate 40a according to a first example of the first embodiment of the present invention. FIG. 6B is a bottom perspective view illustrating the terminal substrate 40a according to the first example of the first embodiment of the present invention.

In the first example illustrated in FIG. 6B, a connection terminal 41a and a dummy connection terminal (also referred to as “first position matching connection terminal”) 45a are formed on one surface of a terminal substrate 40a. The connection terminal 41a is electrically connected to an electrode terminal 42 formed on the other surface of the terminal substrate 40a via a connection electrode 51 (not illustrated in FIGS. 6A and 6B) formed in a through-hole 43 (not illustrated in FIGS. 6A and 6B). A connection terminal 32a and a dummy connection terminal (also referred to as “second position matching terminal”) 33a are provided in a portion of the substrate 30a to be connected to the terminal substrate 40a. The connection terminal 32a is connected to the connection terminal 41a of the terminal substrate 40a. The dummy connection terminal 33a is connected to the dummy connection terminal 45a.

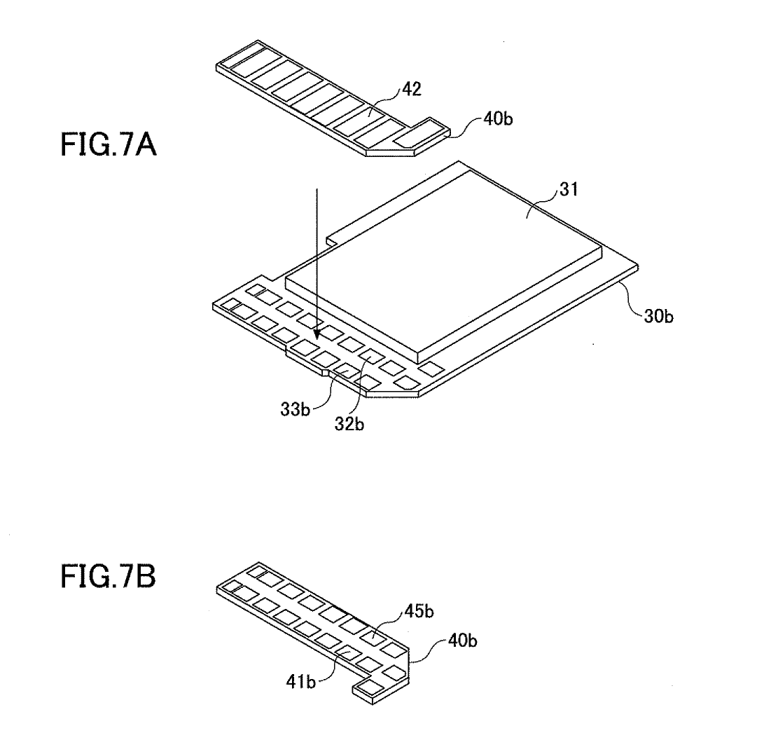

FIG. 7A is a top perspective view illustrating a substrate 30b and a terminal substrate 40b according to a second example of the first embodiment of the present invention. FIG. 7B is a bottom perspective view illustrating the terminal substrate 40b according to the second example of the second embodiment of the present invention.

In the second example illustrated in FIG. 7B, a connection terminal 41b and a dummy connection terminal 45b are provided on a first surface of the terminal substrate 40b. The connection terminal 41b is electrically connected to the electrode terminal 42 formed on the other surface of the terminal substrate 40b via a connection electrode 51 (not illustrated in FIGS. 7A and 7B) formed in a through-hole 43 (not illustrated in FIGS. 7A and 7B). A connection terminal 32b and a dummy connection terminal 33b are provided in a portion of the substrate 30b to be connected to the terminal substrate 40b. The connection terminal 32b is connected to the connection terminal 41b of the terminal substrate 40b. The dummy connection terminal 33b is connected to the dummy connection terminal 45b.

As illustrated in FIG. 6B, the connection terminal 41a and the dummy connection terminal 45a formed in the terminal substrate 40a have a circle shape. As illustrated in FIG. 7B, the connection terminal 41b and the dummy connection terminal 45b formed in the terminal substrate 45 have a quadrangle shape. Nevertheless, the connection terminals 41a, 41b and the dummy connection terminals 45a, 45b may have other shapes as long as the connection terminals 41a, 41b and the dummy connection terminals 45a, 45b can be connected to corresponding connection terminals 32a, 32b and corresponding dummy connection terminals 33a, 33b formed in the substrate 30a, 30b.

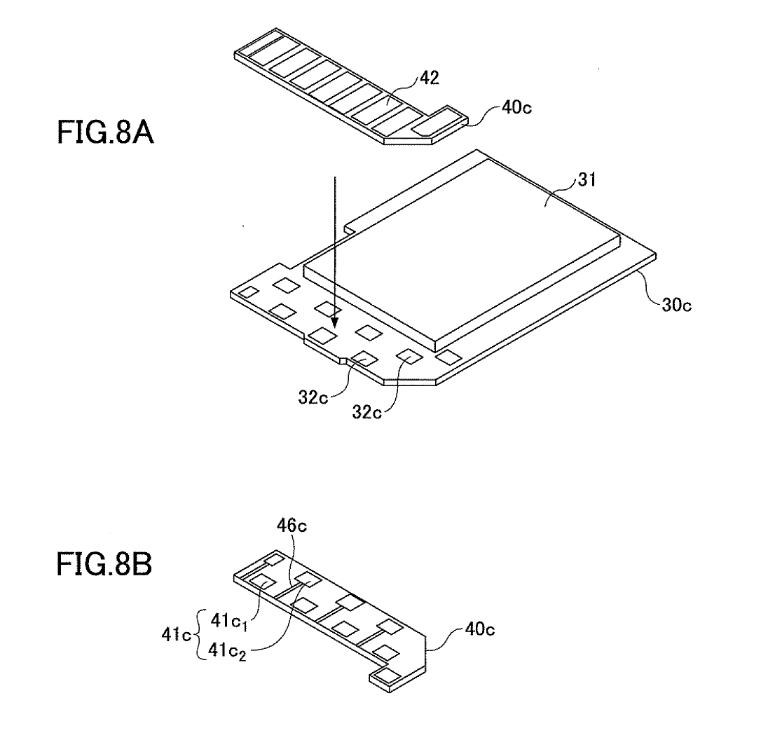

FIG. 8A is a top perspective view illustrating a substrate 30c and a terminal substrate 40c according to a third example of the first embodiment of the present invention. FIG. 8B is a bottom perspective view illustrating the terminal substrate 40c according to the third example of the first embodiment of the present invention.

In the third example illustrated in FIG. 8B, a connection terminal 41c is provided on a first surface of the terminal substrate 40c. The connection terminal 41c is electrically connected to the electrode terminal 42 formed on the other surface of the terminal substrate 40c via a connection electrode 51 (not illustrated in FIGS. 8A and 8B) formed in a through-hole 43 (not illustrated in FIGS. 8A and 8B). The connection terminal 41c includes a first connection terminal part 41c1 and a second connection terminal part 41c2. As illustrated in FIG. 8B, the distance from one end part of the first connection terminal part 41c1 to the other end part of the first connection terminal part 41c1 in the transverse direction of the terminal substrate 40c and the distance from one end part of the second connection terminal part 41c2 to the other end part of the second connection terminal part 41 are different. Thus, the first and second connection terminal parts 41c1, 41c2 having different lengths are alternately arranged on the terminal substrate 40c. The connection terminal 41c is formed in a manner that the first and second connection terminal parts 41c1, 41c2 are prevented from being electrically connected. Therefore, the second connection terminal part 41c2 includes a lead electrode 46c for connecting to a connection electrode 51 (not illustrated in FIGS. 8A and 8B) formed in a through-hole 43 (not illustrated in FIGS. 8A and 8B) of the terminal substrate 40c. A connection terminal 32c is provided in a part of the substrate 30c corresponding to the position of the connection terminal 41c, so that the connection terminal 32c can be connected to a corresponding connection terminal 41c.

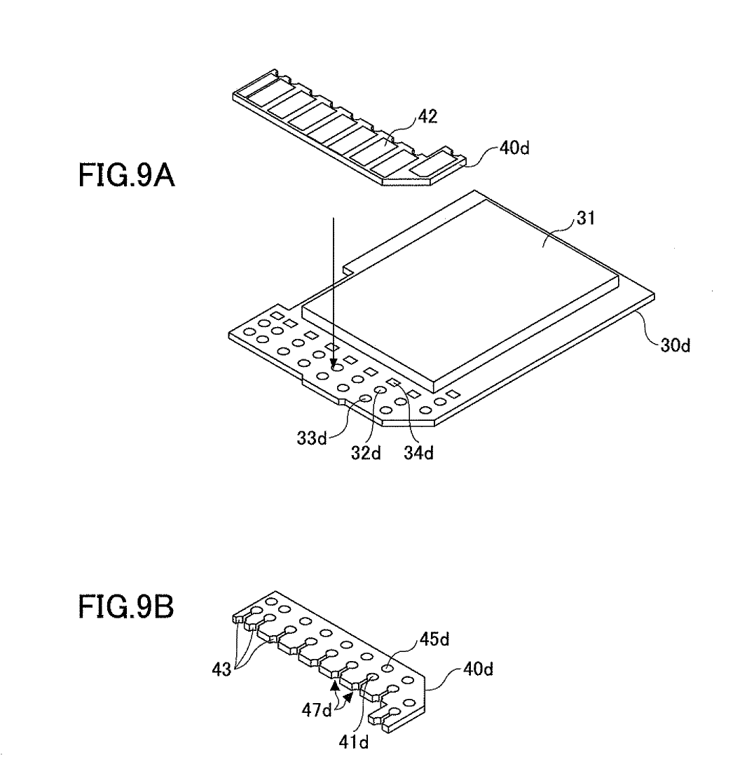

FIG. 9A is a top perspective view illustrating a substrate 30d and a terminal substrate 40d according to a fourth example of the first embodiment of the present invention. FIG. 9B is a bottom perspective view illustrating the terminal substrate 40d according to the fourth example of the first embodiment of the present invention.

In the fourth example illustrated in FIG. 9B, a connection terminal 41d and a dummy connection terminal 45d are provided on a first surface of the terminal substrate 40d. The connection terminal 41d is electrically connected to an electrode terminal 42 provided on a second surface of the terminal substrate 40d via a connection electrode (not illustrated) formed in a part 47d of a through-hole (hereinafter referred to as “through-hole part 47d”). A connection terminal 32d, a dummy connection terminal 33d, and a through-hole electrode connection terminal (also referred to as “position matching connection terminal”) 34d, which are to be connected to the terminal substrate 40, are provided in the substrate 30d in correspondence with the terminal substrate 40. The through-hole electrode connection terminal 34d is for adjusting (matching) the positions of the substrate 30d and the terminal substrate 40d. The terminal substrate 40d and the substrate 30d are connected after adjusting (matching) the position between the through-hole part 47d and the through-hole electrode connection terminal 34d corresponding to the through-hole part 47d. In the case of connecting the terminal substrate 40d and the substrate 30d, the connection terminal 32d is connected to the dummy connection terminal 45d, and the dummy connection terminal 33d is connected to the dummy connection terminal 45d. It is preferable to form the through-hole electrode connection terminal 34d with the same material as, for example, the dummy connection terminal 33d. By forming the through-hole electrode connection terminal 34d with the same material as the dummy connection terminal 45d or the like, manufacturing costs can be prevented from increasing.

In one example for manufacturing the terminal substrate 40d, plural through-holes 43 are formed in a sheet substrate 80 to be used for forming plural terminal substrates 40d. Then, connection electrodes 51 are formed in the through-holes 43 by performing electroplating on the sheet substrate 80. By forming the connection electrodes 51 in the through-holes 43, electric connection can be achieved on both sides (surfaces) of the terminal substrates 40d. Then, by cutting the sheet substrate 80 along the lines that run through the center of the through-holes 43, plural terminal substrates 40d can be obtained. FIG. 9B illustrates an example of one of the terminal substrates 40d obtained by cutting the sheet substrate 80.

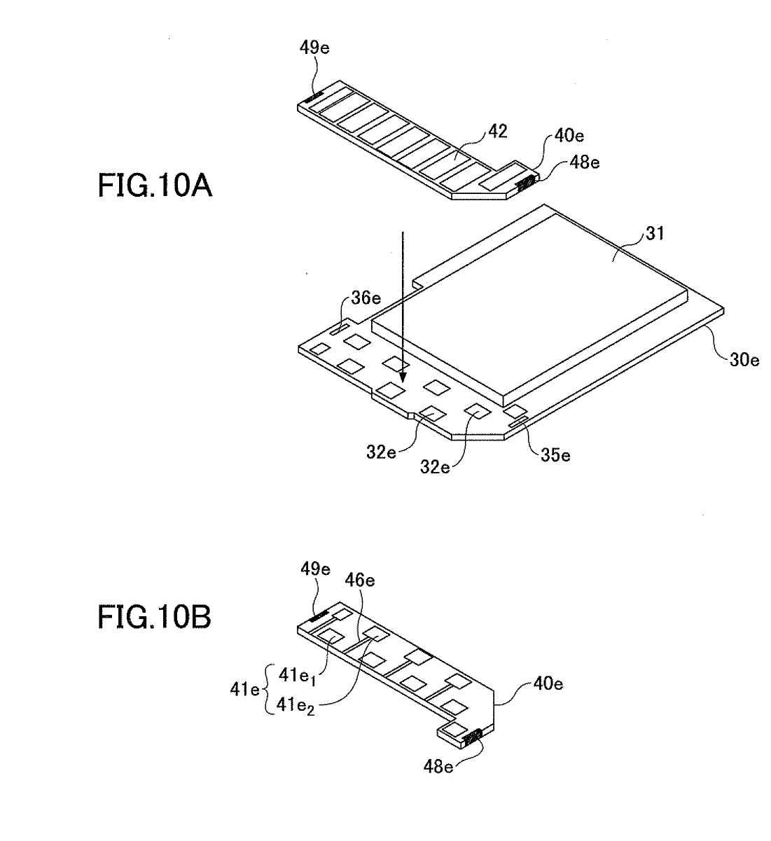

FIG. 10A is a top perspective view illustrating a substrate 30e and a terminal substrate 40e according to a fifth example of the first embodiment of the present invention. FIG. 10B is a bottom perspective view illustrating the terminal substrate 40e according to the fifth example of the first embodiment of the present invention.

In the fifth example illustrated in FIG. 10B, a connection terminal 41e is formed in a first surface of the terminal substrate 40e. The connection terminal 41e is electrically connected to an electrode terminal 42 formed on a second surface of the terminal substrate 40e (formed on an opposite side with respect to the first surface) via a connection electrode 51 (not illustrated in FIGS. 10A and 10B) formed in a through-hole 43 (not illustrated in FIGS. 10A and 10B). The connection terminal 41e includes a first connection terminal part 41e1 and a second connection terminal part 41e2. The first and second connection terminal parts 41e1, 41e2 having different lengths are alternately arranged on the terminal substrate 40e. The connection terminal 41 is formed in a manner that the first and second connection terminal parts 41e1, 41e2 are prevented from being electrically connected. Therefore, the second connection terminal part 41e2 includes a lead electrode 46e for connecting to a connection electrode 51 (not illustrated in FIGS. 10A and 10B) formed in a through-hole 43 (not illustrated in FIGS. 10A and 10B) of the terminal substrate 40e.

Further, position matching electrode terminals 48e and 49e are formed on an end part of each side of the terminal substrate 40e in a longitudinal direction of the terminal substrate 40e. The position matching electrode terminals 48e, 49e are used for position matching (adjustment) between the terminal substrate 40e and the substrate 30e. The terminal substrate 40e and the substrate 30e are connected to each other after adjusting the positions of the position matching electrode terminals 48e, 49e in correspondence with position electrode terminals 35e, 36e of the substrate 30e. A connection terminal 32e is provided in the substrate 30e in correspondence with the position of the connection terminal 41e. Accordingly, the terminal substrate 40e and the substrate 30e are connected by connecting the connection terminal 32e to the connection terminal 41e. It is preferable to form the position matching electrode terminals 35e, 36e, 48e, 49e with the same material as, for example, the connection terminal 41e, the connection terminal 32e, or both the connection terminal 41e and the connection terminal 32e. Thus, manufacturing costs of the card module 100 can be prevented from increasing by forming the position matching electrode terminals 35e, 36e, 48e, 49e with the same material as, for example, the connection terminal 41e, the connection terminal 32e, or both the connection terminal 41e and the connection terminal 32e.

### Second Embodiment

Next, a card module 200 according to a second embodiment of the present invention is described. In this embodiment, an electrode terminal is formed on a substrate without using a terminal substrate.

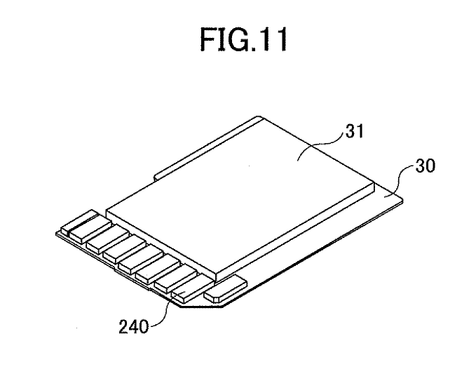

As illustrated in FIG. 11, an electronic device 31 and an electrode terminal 240, being provided on the substrate 30, are connected to each other. The electrode terminal 240 is formed by, for example, performing gold plating on a metal material (e.g., stainless steel or a copper alloy) having a conductive property.

Next, a method for manufacturing a card module 200 according to the second embodiment of the present invention is described.

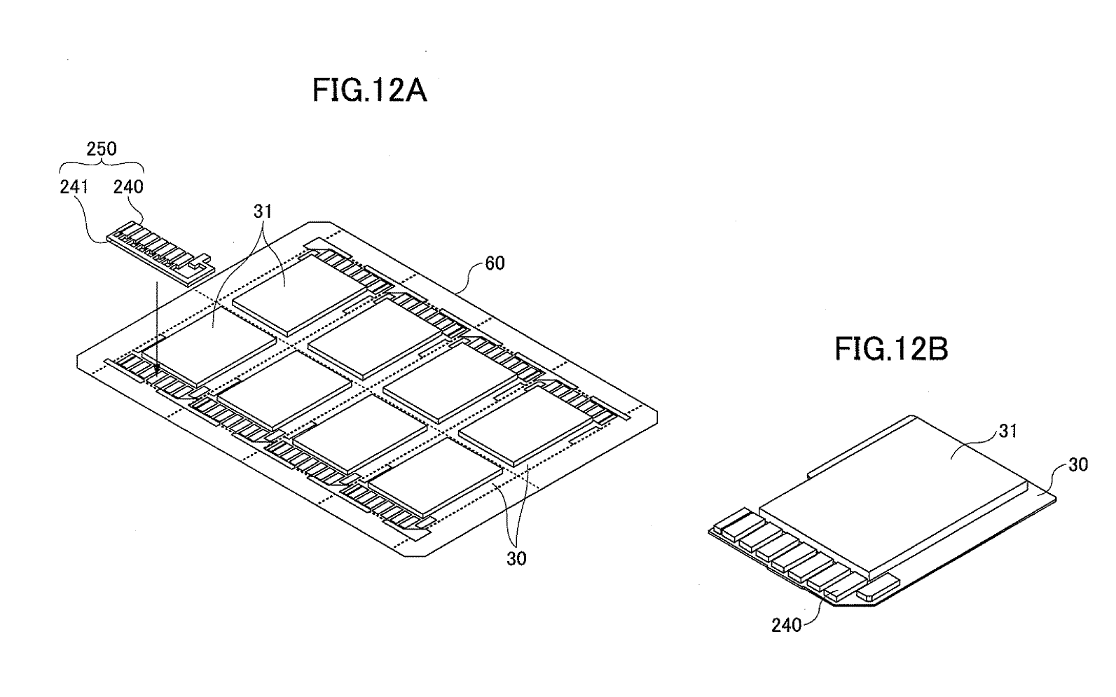

As illustrated in FIGS. 12A and 12B, a sheet substrate 60, which can be cut into one or more separate substrates 30, is prepared. Then, electrode components 250 having plural electrode terminals 240 formed thereon and electronic devices 31 are placed on the sheet substrate 60 and soldered to the sheet substrate 60 by using reflow. Then, the sheet substrate 60 is cut into one or more separate substrates 30. The electrode component 250 includes an electrode terminal frame part 241 that connects the plural electrode terminals 240 with each other. In the case of cutting the sheet substrate 60 into separate substrates 30, the plural electrode terminals 240 and the electrode terminal frame part 241 are cut substantially at the same time. Then, each of the substrates 30, which is cut off from the sheet substrate 60, is provided between a corresponding top case 10 and a corresponding bottom case 20. Thereby, one or more card modules 200 can be obtained. Because the soldering process using reflow is performed at a single time for connecting the substrates 30 and the electrode components 250 and connecting the substrates 30 and the electronic devices 31, the cost for manufacturing the card module 200 can be reduced. That is, the manufacturing cost of the card module 200 can be reduced by soldering the substrates 30 to the electronic components 250 substantially at the same time of soldering the electronic devices 31 to the substrates 30. As one example for manufacturing the electrode component 250, there is a method of mold-cutting a metal plate (e.g., stainless steel plate) into a shape of the electrode component 250 and performing a gold plating process on the mold-cut metal plate.

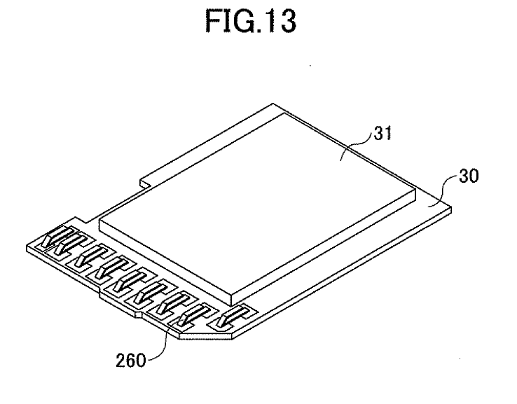

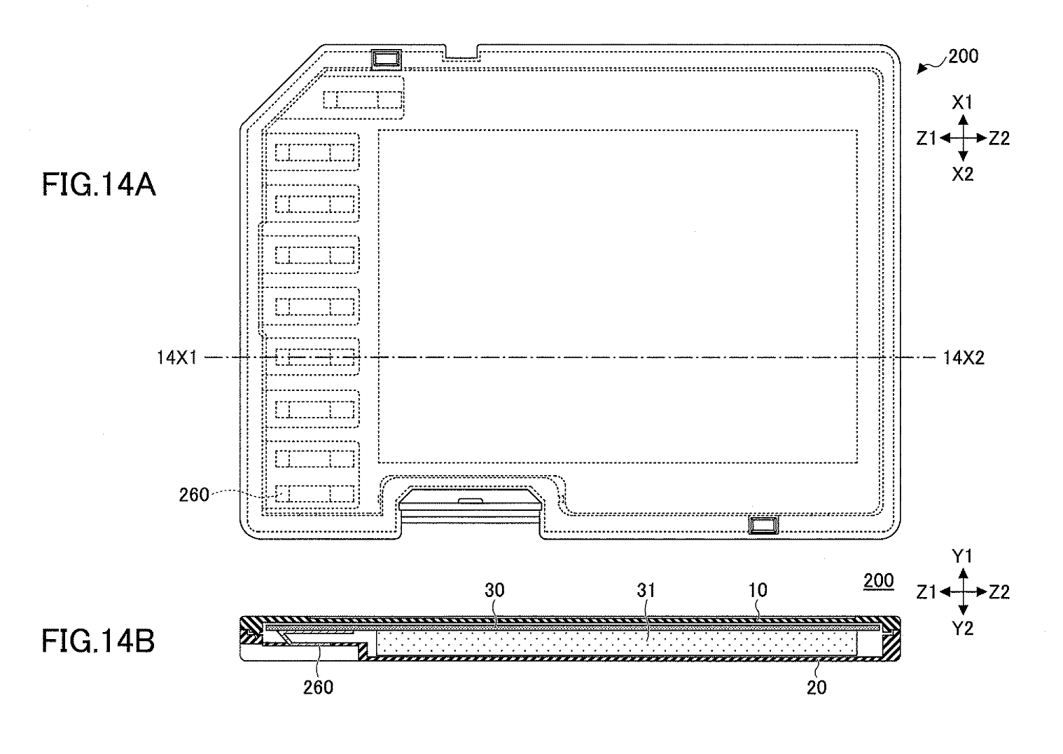

Alternatively, it may be preferable for an electrode terminal formed on the substrate 30 to have a spring-like (resilient) property. Accordingly, a spring electrode terminal 260 having a spring-like (resilient) property and a U-letter shape may be used as an alternative of the above-described electrode terminal 240. FIG. 14A is a schematic diagram illustrating a back surface of another card module according to the second embodiment of the present invention. FIG. 14B is a cross-sectional view of the card module taken along a dash-dot line 14X1-14X2 in FIG. 14A. As illustrated in FIGS. 13 and 14A, 14B, the spring electrode terminal 260 may be formed in a position of the electrode terminal 240 illustrated in FIG. 11. In the case of using the spring electrode terminal 260, the spring electrode terminal 260 is provided in a predetermined position so that the spring electrode terminal 260 is connected to the bottom case 20 in a manner where at least a surface of the spring electrode terminal 260 facing the bottom case 20 is exposed. Accordingly, owing to the spring-like property of the spring electrode terminal 260, the card module 200 can be positively connected to an electrode terminal (not illustrated) of a card slot 110.

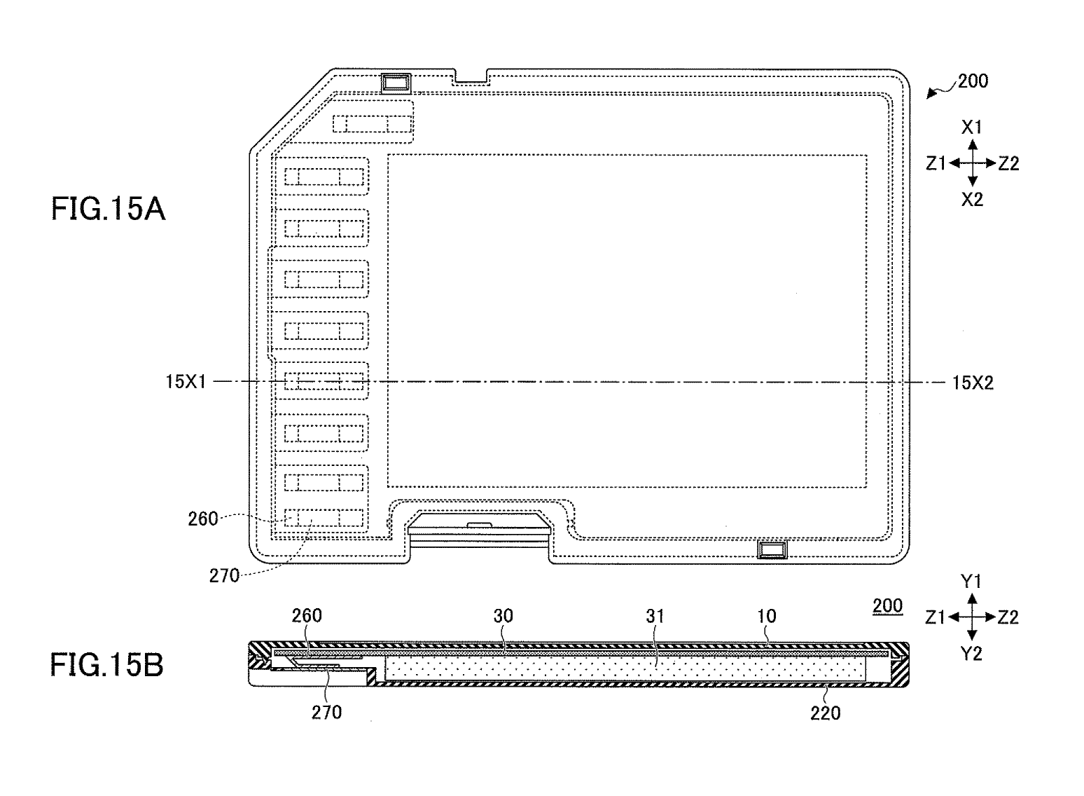

Alternatively, instead of forming the spring electrode terminal 260 on the substrate 30 in an exposed state (as illustrated in FIGS. 14A and 14B), the spring electrode terminal 260 may be formed on the substrate 30 in a manner contacting a back surface of an electrode terminal 270 provided in a bottom case 220. FIG. 15A is a schematic diagram illustrating a back surface of yet another card module according to the second embodiment of the present invention. FIG. 15B is a cross-sectional view of the card module taken along a dash-dot line 15X1-15X2 in FIG. 15A. As illustrated in FIGS. 15A and 15B, the bottom case 220, which is formed of a resin material, may be integrally formed (i.e. form a united body) with the electrode terminal 270 by insert molding. Accordingly, in this alternative example of the second embodiment, the card module 200 has the spring electrode terminal 260 of the substrate 30 contacting the back surface of the electrode terminal 270.

Other than the above, the configuration of the card module 200 of the second embodiment is substantially the same as the configuration of the card module 100 of the first embodiment.

### Third Embodiment

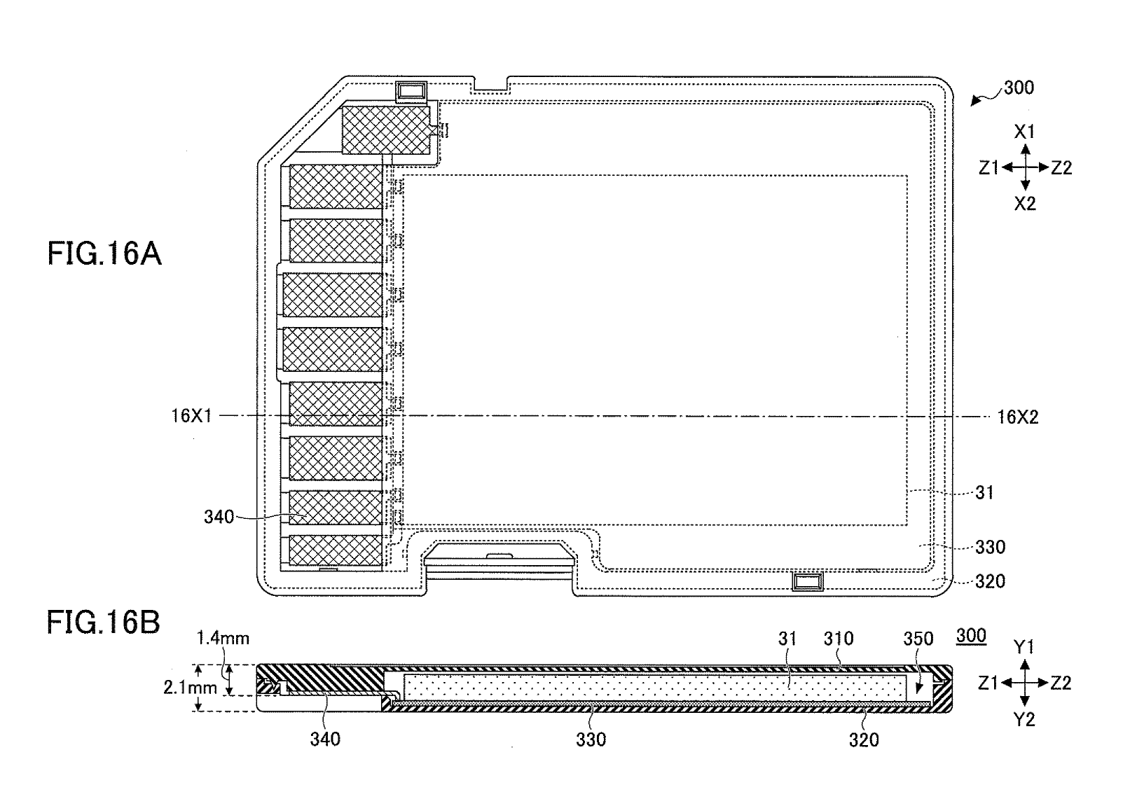

Next, a card module 300 according to a third embodiment of the present invention is described with reference to FIGS. 16A and 16B. FIG. 16A is a bottom view of the card module 300 according to the third embodiment of the present invention, FIG. 16B is a cross-sectional view taken along a dot-dash line 16X1-16X2 of FIG. 16A.

The card module 300 includes a top case 310, a bottom case 320, and a substrate 330 provided between the top case 310 and the bottom case 320. The substrate 330 is provided in a manner contacting an inner surface of the bottom case 320 without being bent. An external connection terminal 340 is connected to one end part of the substrate 330. The external connection terminal 340 is formed by processing a metal material or a metal substrate. In this embodiment, a part of the external connection terminal 340 is bent, so that the bent part can be connected to the substrate 330. The bottom case 320 is formed in a manner that the external connection terminal 340 is exposed.

The space 350 is formed in an area surrounded by the top case 310 and the bottom case 320. The top case 310 and the bottom case 320 are engaged with each other in a manner that the electronic device 31 mounted on the substrate 330 is installed inside the space 350. In order to make the most of the space 350, it is preferable to provide the substrate 330 in contact with the inner surface (in this embodiment, inner bottom surface) of the bottom case 320 and mount the electronic device 31 on the inner bottom surface of the substrate 330 facing the space 350.

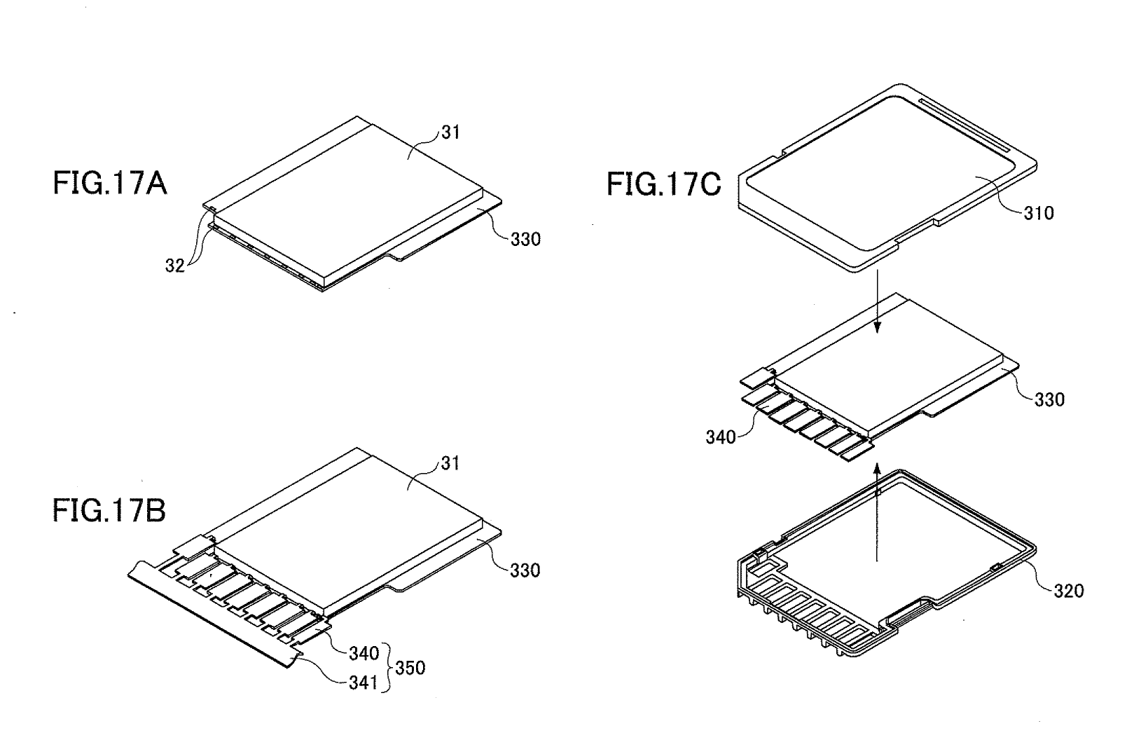

Next, another method for manufacturing a card module 300 according to the third embodiment of the present invention is described with FIGS. 17A-17C.

As illustrated in FIG. 17A, the electronic device 31 is mounted on the substrate 330, for example, by soldering with reflow.

As illustrated in FIG. 17B, the external connection terminal 340 is connected to a corresponding connection terminal 32 (see, for example, FIG. 17A) of the substrate 330, for example, by soldering. More specifically, for example, an electrode component 350 including plural of the external connection terminals 340 connected to an electrode terminal frame part 341 is prepared. Then, the plural external connection terminals 340 are soldered to corresponding connection terminals 32 of the substrate 330 provided at an end part of the substrate 330. Then, the electrode terminal frame part 341, which is connected to the plural external connection terminals 340, is cut off from the substrate 330. Then, as illustrated in FIG. 17C, the substrate 330 is placed between the top case 310 and the bottom case 320. Then, the top case 310 and the bottom case 320 are engaged with each other in a manner having the substrate 330 provided therebetween. Thereby, the card module 300 can be obtained.

Other than the above, the configuration of the card module 300 of the third embodiment is substantially the same as the configuration of the card module 100 of the first embodiment.

Further, the present invention is not limited to these embodiments, but variations and modifications may be made without departing from the scope of the present invention.

The present application is based on Japanese Priority Application No. 2010-186531 filed on Aug. 23, 2010, with the Japanese Patent Office, the entire contents of which are hereby incorporated by reference.

What is claimed is:

1. A card module comprising:
a top case;
a bottom case engaged with the top case;
a substrate being positioned between the top case and the bottom case and including a first connection terminal;
an electronic device provided in a space formed by engaging the top case with the bottom case; and
a terminal substrate including a first surface on which a second connection terminal is formed, a second surface on which an electrode terminal is formed, and a through-hole in which a connection electrode is formed;
wherein the first connection terminal is connected to the second connection terminal; and
wherein the second connection terminal and the electrode terminal are connected via the connection electrode.

2. The card module as claimed in claim 1, wherein the terminal substrate has a first end positioned towards a side of the card module from which the card module is inserted to a card slot, wherein the through-hole is positioned towards a second end of the terminal substrate located opposite from the first end.

3. The card module as claimed in claim 1, further comprising:
a first position matching connection terminal provided on a predetermined part of the terminal substrate; and
a second position matching connection terminal provided on the substrate corresponding to the predetermined part of the first position matching connection terminal.

4. The card module as claimed in claim 3, wherein the first and second position matching connection terminals are formed with the same material as a material of at least one of the first connection terminal and the second connection terminal.

5. A card module comprising:
a top case;
a bottom case engaged with the top case;
a substrate being positioned between the top case and the bottom case and including a first connection terminal;
an electronic device provided in a space formed by engaging the top case with the bottom case; and
an electrode terminal being connected to the substrate and including an exposed surface facing the bottom case;
wherein the electronic device and the electrode terminal are formed on a same plane of the substrate.

6. The card module as claimed in claim 5, wherein the electrode terminal has a spring-like property.

7. The card module as claimed in claim 5, further comprising:
an external electrode terminal formed in a part of the bottom case;
wherein the electrode terminal and the external electrode terminal contact each other at an inner surface of the bottom case.

8. A card module comprising:
a top case;
a bottom case engaged with the top case;
a substrate being positioned between the top case and the bottom case;
an electronic device provided in a space formed by engaging the top case with the bottom case; and
an external electrode terminal being connected to an end part of the substrate and including an exposed surface facing the bottom case.

9. A method for manufacturing a card module, the method comprising:
placing an electronic device on a substrate;
placing a terminal substrate on a sheet substrate, the terminal substrate including a first surface on which a connection terminal is formed, a second surface on which an electrode terminal is formed, and a through-hole in which a connection electrode is formed;
soldering the substrate to the terminal substrate substantially at the same time of soldering the electronic device to the sheet substrate;
positioning the substrate between a top case and a bottom case; and
engaging the top case with the bottom case, so that the electronic device being soldered to the substrate is provided in a space formed by engaging the top case with the bottom case;
wherein the top case and the bottom case are engaged in a manner that the connection terminal and the electrode terminal are connected via the connection electrode.

10. A method for manufacturing a card module, the method comprising:
placing an electronic device on a substrate;
placing an electronic component on the substrate, the electronic component including a frame part having a plurality of electrode terminals formed thereon;
soldering the substrate to the electronic component;
soldering the electronic device to the substrate;
cutting the frame part into the plural electrode terminals;
positioning the substrate between a top case and a bottom case; and
engaging the top case with the bottom case, so that the electronic device being soldered to the substrate is provided in a space formed by engaging the top case with the bottom case;
wherein the top case and the bottom case are engaged in a manner that the electronic device and each of the plural electrode terminals are formed on a same plane of the substrate.

11. The method as claimed in claim 10, wherein the soldering of the substrate to the electronic components is performed substantially at the same time of the soldering of the electronic device to the substrate.

12. A method for manufacturing a card module, the method comprising:
placing an electronic device on a substrate including an end part having a plurality of electrode terminals formed thereon;
placing an electronic component on the substrate, the electronic component including a frame part having a plurality of electrode terminals formed thereon;
soldering the substrate to the electronic component;
soldering the electronic device to the substrate;
cutting off the frame part from the electronic component being soldered to the substrate;
positioning the substrate between a top case and a bottom case; and
engaging the top case with the bottom case, so that the electronic device of the substrate is provided in a space formed by engaging the top case with the bottom case;
wherein the top case and the bottom case are engaged in a manner that the electronic component includes an exposed surface facing the bottom case.

13. The method as claimed in claim 11, wherein the soldering of the substrate to the electronic component is performed substantially at the same time of the soldering of the electronic device to the substrate.
